(19) United States
(12) Patent Application Publication
(10) Pub. No.: US 2019/0272874 A1
(43) Pub. Date: Sep. 5, 2019

(54) MEMORY DEVICE, METHOD OF FORMING THE SAME, METHOD FOR CONTROLLING THE SAME AND MEMORY ARRAY

(71) Applicant: Nanyang Technological University, Singapore (SG)

(72) Inventors: Putu Andhita Dananjaya, Singapore (SG); Wen Siang Lew, Singapore (SG)

(21) Appl. No.: 16/338,033

(22) PCT Filed: Sep. 12, 2017
(86) PCT No.: PCT/SG2017/050457

§ 371 Date: Mar. 29, 2019

(30) Foreign Application Priority Data
Sep. 29, 2016 (SG) 10201608151Q

(51) Int. Cl. G11C 13/00; H01L 45/00; H01L 27/24

(52) U.S. Cl. CPC G11C 13/0007; G11C 13/0011; H01L 45/08; H01L 45/1233; H01L 45/142; H01L 45/143; H01L 45/1266; H01L 45/146; H01L 27/24; G11C 2213/15; G11C 2213/50; G11C 2213/77; H01L 45/144

(57) ABSTRACT

According to embodiments of the present invention, a memory device is provided. The memory device includes an electrochemical metallization memory (ECM) cell and a valence change memory (VCM) cell arranged one over the other. According to further embodiments of the present invention, a method of forming a memory device, a method for controlling a memory device, and a memory array are also provided.

### CROSS-REFERENCE TO RELATED APPLICATION

This application claims the benefit of priority of Singapore patent application No. 10201608151Q, filed 29 Sep. 2016, the content of it being hereby incorporated by reference in its entirety for all purposes.

### TECHNICAL FIELD

Various embodiments relate to a memory device, a method of forming the same, a method for controlling the same, and a memory array.

### BACKGROUND

Resistive Random Access Memory (RRAM) has emerged as one of the strong candidates for non-volatile memory technology in near future, along with magnetic RAMs (MRAMs), ferroelectric RAMs (FRAMs), and phase-change RAMs (PRAMs). Flash semiconductor is the current baseline for non-volatile memory (NVM) technology for electronics devices. It has several weaknesses in terms of endurance and high operating power. Flash scalability was once an issue for high density memory applications, but the success of 3D NAND flash, which is expected to enter the market aggressively, certainly pushes the NVM density limit to a higher level for the next few years. Each NVM technology has its advantages according to its unique property. For instance, MRAM has its weakness in scaling but has high read-write endurance and excellent low power consumption property, hence it is more suitable for embedded memory device applications such as automotive. 3D NAND flash may have scaling advantage but cannot avoid the natural low endurance and high write current issues.

RRAM has been targeted as mass storage NVM due to its silicon technology compatibility and excellent scalability while being able to maintain high performance compared to the current baseline (Flash) and other emerging technologies. RRAM cell is a two-terminal structure of an insulator sandwiched in between two metal electrodes that can be switched between two or more resistance states. The resistance states can be altered from high resistance states (HRS) to low resistance states (LRS) and vice versa by applying the appropriate voltage (SET and RESET voltage) across the device. Because of its two-terminal nature, individual RRAM cell can be easily integrated into the crossbar arrays architecture. This architecture offers high memory density as well as high degree of interconnectivity between the row and column of electrodes allowing random write and read operation of memory bit.

Based on the resistance switching mechanism, RRAM can be classified into two main groups, i.e., electrochemical metallization memory (ECM) and valence change memory (VCM). In general, ECM cells include a chalcogenide, solid electrolyte, or oxide insulating layer placed in between a reactive and an inert electrode. The resistance switching mechanism is based on the formation and dissolution of conductive filaments due to the reactive electrode cation motion (includes silver (Ag), copper (Cu), and nickel (Ni)) under the influence of an external electric field. On the other hand, VCM cells include a metal oxide insulating layer sandwiched between ohmic and inert electrodes. The switching mechanism of VCM is driven by migration of oxygen ions and/or vacancies.

Device resistance (ON/OFF) ratio is one of the most important device parameters that can reflect the performance of the RRAM devices. High ON/OFF ratio is required to minimize bit error during operation and to achieve high retention capability of the device. Furthermore, it will also provide a bigger window to obtain low power consumption by increasing the LRS value of the device. Another important parameter for device operation is the requirement of compliance current. During the SET operation, there will be a sudden jump in the current flowing across the device. Thus, limiting the current value during the SET operation is critical to avoid permanent damage of the device. The current can be limited by programming the compliance current through an external circuit or designing the device structure such that it can exhibit self-compliant characteristics.

### SUMMARY

The invention is defined in the independent claims. Further embodiments of the invention are defined in the dependent claims.

According to an embodiment, a memory device is provided. The memory device may include an electrochemical metallization memory (ECM) cell and a valence change memory (VCM) cell arranged one over the other.

According to an embodiment, a method of forming a memory device is provided. The method may include arranging an electrochemical metallization memory (ECM) cell and a valence change memory (VCM) cell one over the other.

According to an embodiment, a method for controlling a memory device is provided. The method may include applying an electric field to the memory device including an electrochemical metallization memory (ECM) cell and a valence change memory (VCM) cell arranged one over the other.

According to an embodiment, a memory array is provided. The memory array may include a plurality of first electrode lines, a plurality of second electrode lines, and a plurality of memory devices, wherein, for each memory device of the plurality of memory devices, the memory device is arranged between a respective first electrode line of the plurality of first electrode lines and a respective second electrode line of the plurality of second electrode lines, and is as described herein.

### BRIEF DESCRIPTION OF THE DRAWINGS

In the drawings, like reference characters generally refer to like parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic cross-sectional view of a memory device, according to various embodiments.

FIG. 1B shows a method of forming a memory device, according to various embodiments.

FIG. 1C shows a method for controlling a memory device, according to various embodiments.

FIG. 1D shows a schematic cross-sectional view of a memory array, according to various embodiments.

FIGS. 2A to 2I show, as cross-sectional views, various processing stages of a method for fabricating an electrochemical metallization memory (ECM) cell, according to various embodiments.

FIGS. 3A to 3C show plots of measurement data of MgO-based ECM structures.

FIG. 4 shows cross-sectional views of self-compliance mechanism of a Cu/MgO-based RRAM through heat assisted Cu filaments oxidation.

FIGS. 5A and 5B show plots of electrical measurement results of individual RRAM cells.

FIGS. 6A to 6C show cross-sectional views of a memory device with the associated operation mechanisms, according to various embodiments.

FIGS. 6D to 6F show cross-sectional views of a memory device with the associated operation mechanisms, according to various embodiments.

FIG. 7A shows a plot of full IV (current-voltage) loop for a memory device of various embodiments.

FIG. 7B shows a plot of resistance for different high and low resistance states for the two memory cells of a memory device of various embodiments.

FIGS. 8A and 8B show schematic perspective views of different arrangements for a memory device of various embodiments.

FIGS. 9A to 9I show, as cross-sectional views, various processing stages of a method for fabricating a memory device, according to various embodiments.

FIGS. 10A to 10E show, as cross-sectional views, various processing stages of a method for fabricating a memory device, according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other methods or devices. Similarly, embodiments described in the context of a method are analogously valid for a device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the phrase “at least substantially” may include “exactly” and a reasonable variance.

In the context of various embodiments, the term “about” or “approximately” as applied to a numeric value encompasses the exact value and a reasonable variance.

As used herein, the term “and/or” includes any and all combinations of one or more of the associated listed items.

As used herein, the phrase of the form of “at least one of A or B” may include A or B or both A and B. Correspondingly, the phrase of the form of “at least one of A or B or C”, or including further listed items, may include any and all combinations of one or more of the associated listed items.

Various embodiments may provide anti-serially connected resistive random access memory cells.

Various embodiments may provide a structure of resistive Random Access Memory (RRAM) device that may achieve self-compliant characteristics, low power consumption, and high ON/OFF ratio. The individual RRAM structure may include anti-serially connected electrochemical metallization memory (ECM) and valence change memory (VCM) cells. The two connected RRAM cells may be required to have compatible high and low resistance state (HRS and LRS) values to allow efficient voltage shifts during the operation. The electroforming process to initiate the switching operation may be done by the formation of conductive filaments in the VCM cell. The successive cell operations may be indicated by simultaneous formation and rupture of conductive filaments at different RRAM cells (ECM and VCM) resulting in self-compliance characteristics. The ECM cell may give rise to a high ON/OFF ratio while the VCM cell may allow self-compliant electroforming process.

In general, an ECM cell or structure with a large ON/OFF ratio has both unipolar and bipolar switching. Nevertheless, the memory device of various embodiments, which may include an ECM cell, may exhibit only bipolar switching mechanism.

It should be appreciated that while the memory device (RRAM) of various embodiments may be described herein as having an electrochemical metallization memory (ECM) cell and a valence change memory (VCM) cell (for example, anti-serially connected ECM cell and VCM cell) by way of non-limiting examples, the memory device (RRAM) may include two ECM cells connected anti-serially, or two VCM cells connected anti-serially. In various embodiments, any one of the arrangement of two ECM cells, two VCM cells, and one ECM cell and one VCM cell, connected anti-serially to each other, may include different materials and/or layer arrangements. This may mean that the memory device may have an asymmetrical arrangement.

Various embodiments may also provide a memory array having a plurality of memory devices described herein. The memory array, with the associated electrode lines, may be arranged in a crossbar architecture or arrangement as will be described further below.

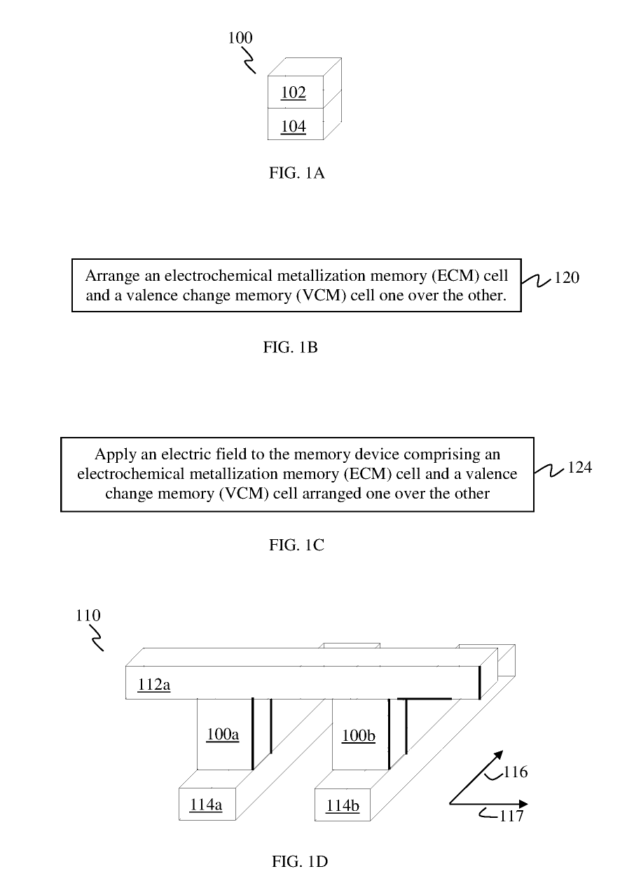

FIG. 1A shows a schematic cross-sectional view of a memory device 100, according to various embodiments. The memory device 100 includes an electrochemical metallization memory (ECM) cell 102 (or 104) and a valence change memory (VCM) cell 104 (or 102) arranged one over the other.

In other words, a memory device 100 having a combination or stack of an ECM cell and a VCM cell may be provided. The ECM cell 102 may be arranged on top of or over the VCM cell 104, or the VCM cell 102 may be arranged on top of or over the ECM cell 104. Descriptions are provided herein based on the non-limiting example of the ECM cell (e.g., 102) being provided on top of or over the VCM cell (e.g., 104), although it should be appreciated that the order of arrangement may be reversed as described above.

In various embodiments, the ECM cell 102 and the VCM cell 104 may be connected to one another, for example, the ECM cell 102 and the VCM cell 104 may be in contact with each other.

In various embodiments, the ECM cell 102 and the VCM cell 104 may be arranged anti-serially to one another. The ECM cell 102 and the VCM cell 104 may be connected anti-serially to one another, for example, the ECM cell 102 and the VCM cell 104 may be in contact with each other in an anti-serial connection.

It should be appreciated that each of the ECM cell 102 and the VCM cell 104 may include or may be a resistive memory cell. This may mean that the ECM cell 102 and the VCM cell 104 may be capable of storing information or data based on a resistive or resistance state (or value) of the memory cell. Accordingly, it should be appreciated that the resistive or resistance state of at least one of the ECM cell 102 or the VCM cell 104 may be changed to store different information.

In the context of various embodiments, an “electrochemical metallization memory cell” and its acronym, an “ECM cell”, may mean a resistive memory cell having a resistive (or resistance) switching mechanism based on the formation and dissolution (or rupture) of conductive paths (or filaments) due to the motion of one or more cations of the associated reactive electrode under influence of an (external) electric field.

In the context of various embodiments, a “valence change memory cell” and its acronym, a “VCM cell”, may mean a resistive memory cell having a resistive (or resistance) switching mechanism based on migration of oxygen ions and/or vacancies.

Migration of charged particles (e.g., ions) in the ECM cell 102 and the VCM cell 104 may be triggered by an (external) electric field (E) provided by an (external) bias.

In various embodiments, in response to an electric field applied to or across the memory device 100, for example, across the ECM cell 102 and the VCM cell 104, the ECM cell 102 and the VCM cell 104 may be configured to switch or may be capable of switching in a complementary manner relative to each other. This may mean that complementary resistive switching (e.g., opposite switching process) between the ECM cell 102 and the VCM cell 104 may be achieved. The respective states of the ECM cell 102 and the VCM cell 104 resulting from the complementary resistive switching may depend on the switching polarity applied to the ECM cell 102 and the VCM cell 104.

In various embodiments, the ECM cell 102 and the VCM cell 104 may be arranged asymmetrically to one another, or, in other words, the ECM cell 102 and the VCM cell 104 may include different materials, e.g., in one or more corresponding layers of the ECM cell 102 and the VCM cell 104. Put in another way, the ECM cell 102 and the VCM cell 104 may have different structures (e.g., different metal/insulator/metal structures (combination of layers)) as a result of the different materials used. As a result, the memory device 100 may have an asymmetrical arrangement. As a non-limiting example, the respective insulating layers of the ECM cell 102 and the VCM cell 104 may include different materials. Accordingly, by being arranged (or connected) asymmetrically to one another, the ECM cell 102 and the VCM cell 104 may be different in at least one of material, layer or stack arrangement, or structure.

As a non-limiting example, where the ECM cell 102 and the VCM cell 104 may be in contact with each other with an interface defined therebetween, the ECM cell 102 and the VCM cell 104 may be arranged asymmetrically with respect to an axis at or along the interface. Where the ECM cell 102 and the VCM cell 104 may be arranged sharing a common element (e.g., an electrode), the ECM cell 102 and the VCM cell 104 may be arranged asymmetrically with respect to a central axis of the common element.

In the context of various embodiments, the ECM cell 102 and the VCM cell 104 may have significantly different high resistance values. The combination of the ECM cell 102 and the VCM cell 104 may provide one or more of the following. Firstly, during the forming process (e.g., the first switching), the VCM cell 104 may provide self-compliant characteristics, thus, a more controllable forming process may be achieved.

Secondly, the high ON/OFF ratio of the ECM cell 102 may provide more efficient voltage shift during the switching process and furthermore may maintain a high ratio between the resistance states.

In the context of various embodiments, each of the ECM cell 102 and the VCM cell 104 may include a metal/insulator/metal arrangement or stack.

In the context of various embodiments, each of the ECM cell 102 and the VCM cell 104 may be or may include a resistive random-access memory (RRAM) cell. The RRAM cell may include a metal/insulator/metal arrangement or stack.

In the context of various embodiments, each of the ECM cell 102 and the VCM cell 104 may be a bipolar memory cell, meaning that opposite directions of electric field may be required to switch the resistance state of at least one of the ECM cell 102 or the VCM cell 104.

In the context of various embodiments, each of the ECM cell 102 and the VCM cell 104 may be a non-volatile memory cell. Accordingly, it should be appreciated that the memory device 100 may be a non-volatile memory device.

In various embodiments, in response to an electric field applied to the memory device 100, one or more conductive paths (e.g., conductive filaments) may be formed (e.g., to allow propagation of an electrical signal) in one of the ECM cell 102 and the VCM cell 104 to define a first resistance state for the corresponding memory cell 102 or 104, and one or more conductive paths (e.g., conductive filaments) may be ruptured (e.g., to prevent propagation of an electrical signal) in the other of the ECM cell 102 and the VCM cell 104 to define a second resistance state for the corresponding memory cell 104 or 102. The second resistance state may be different from the first resistance state, for example, higher than the first resistance state, e.g., in terms of resistance value.

In the context of various embodiments, charged particles (e.g., ions) in the corresponding memory cell may migrate (and assemble) to form one or more conductive paths. Where one or more conductive paths are formed, the corresponding memory cell may be at least substantially conductive, and a low resistance state (LRS) may be defined in the corresponding memory cell.

In the context of various embodiments, charged particles (e.g., ions) in the corresponding memory cell may be removed from one or more conductive paths to rupture the conductive path(s). Where one or more conductive paths are ruptured, the corresponding memory cell may be at least substantially non-conductive, and a high resistance state (HRS) may be defined in the corresponding memory cell.

In various embodiments, in response to another electric field of an opposite polarity applied to the memory device 100, one or more conductive paths (e.g., conductive filaments) may be ruptured in the one of the ECM cell 102 and the VCM cell 104 to define the second resistance state for the corresponding memory cell 102 or 104, and one or more conductive paths (e.g., conductive filaments) may be formed in the other of the ECM cell 102 and the VCM cell 104 to define the first resistance state for the corresponding memory cell 104 or 102.

For example, in response to a first electric field applied to the memory device 100, one or more conductive paths may be formed in the ECM cell 102 to define the first resistance state, and one or more conductive paths may be ruptured in the VCM cell 104 to define the second resistance state. Further, in response to a second electric field of an opposite (or reverse) polarity applied to the memory device 100, one or more conductive paths may be ruptured in the ECM cell 102 to define the second resistance state, and one or more conductive paths may be formed in the VCM cell 104 to define the first resistance state. In this way, there may be complementary resistive switching (or opposite switching process) between the ECM cell 102 and the VCM cell 104. For example, when one memory cell 102 or 104 undergoes a SET process (formation of one or more conductive paths), the other (complementary) memory cell 104 or 102 undergoes a RESET process (rupture of one or more conductive paths).

In various embodiments, in response to an electric field applied to the memory device 100, there may be at least simultaneous formation and rupture of one or more conductive paths in respective different memory cells, resulting in self-compliance characteristics. Nevertheless, depending on the required properties, it should be appreciated that the formation and rupture of one or more conductive paths may not necessarily be simultaneous. If the switching occurs simultaneously, there may only be two memory states in one memory device, and a lower energy consumption may be achieved. Further, simultaneous switching may lead to a small ΔV, where ΔV refers to the voltage window in which both the ECM and VCM cells are in the low resistance state. If the switching does not occur simultaneously, the corresponding resistance may be used as another memory state which may give rise to multibit storage capability; however, a relatively higher energy may be required for the device operation.

In various embodiments, the ECM cell 102 may include a first insulating layer (or first insulator), and, the VCM cell 104 may include a second insulating layer (or second insulator). In response to the corresponding electric field, one or more conductive paths may be formed in or throughout one of the first and second insulating layers to define the first resistance state for the corresponding memory cell, and one or more conductive paths may be ruptured in the other of the first and second insulating layers to define the second resistance state for the corresponding memory cell.

In various embodiments, the first insulating layer and the second insulating layer may be arranged coaxially, or co-aligned to each other. This may mean that the respective central axis of each of the first and second insulating layers may be co-aligned to each other.

In various embodiments, the first insulating layer and the second insulating layer may be arranged offset from each other (or non-coaxially to one another).

In the context of various embodiments, the first insulating layer may include an oxide or a chalcogenide or an amorphous material.

In the context of various embodiments, the second insulating layer may include an oxide.

In the context of various embodiments, the oxide may include at least one of magnesium oxide (MgO), aluminium oxide (AlOx), silicon oxide (SiOx), tantalum oxide (TaOx), zinc oxide (ZnO) or other transition metal oxides.

In the context of various embodiments, the chalcogenide may include at least one of germanium disulfide (GeS₂), germanium selenide (GeSex), germanium telluride (GeTe), copper(I) sulfide (Cu₂S), silver sulfide (Ag₂S), or other chalcogenide-based materials.

In the context of various embodiments, the amorphous material may include at least one of silicon nitride (Si₃N₄), silicon (Si) or other amorphous materials.

In various embodiments, the ECM cell 102 may include a first electrode and an intermediate electrode arrangement sandwiching the first insulating layer, and the VCM cell 104 may include a second electrode and the intermediate electrode arrangement sandwiching the second insulating layer. In response to the corresponding electric field, one or more conductive paths may be formed from the first electrode to the intermediate electrode arrangement (or from the intermediate electrode arrangement to the first electrode) through the first insulating layer to define the first resistance state for the ECM cell 102, or one or more conductive paths may be formed from the second electrode to the intermediate electrode arrangement (or from the intermediate electrode arrangement to the second electrode) through the second insulating layer to define the first resistance state for the VCM cell 104.

The first insulating layer may be arranged in contact with at least one of the first electrode or the intermediate electrode arrangement. The second insulating layer may be arranged in contact with at least one of the second electrode or the intermediate electrode arrangement. The intermediate electrode may be arranged in contact with at least one of the first insulating layer or the second insulating layer.

In various embodiments, the first electrode may include or may define a top electrode (TE), while the second electrode may include or may define a bottom electrode (BE), or vice versa.

In various embodiments, at least one of the first electrode or the second electrode may be in the form of an electrode line, meaning that the first electrode and/or the second electrode may extend longitudinally.

In various embodiments, the intermediate electrode arrangement may be shared by or common to the ECM cell 102 and the VCM cell 104.

In various embodiments, the intermediate electrode arrangement may include a first intermediate electrode (e.g., as part of the ECM cell 102) and a second intermediate electrode (e.g., as part of the VCM cell 104). The first intermediate electrode and the second intermediate electrode may be arranged one over the other with the first intermediate electrode arranged proximal to the first insulating layer and the second intermediate electrode arranged proximal to the second insulating layer. The first insulating layer may be sandwiched by the first electrode and the first intermediate electrode, and the second insulating layer may be sandwiched by the second electrode and the second intermediate electrode. The first insulating layer may be arranged in contact with at least one of the first electrode or the first intermediate electrode. The second insulating layer may be arranged in contact with at least one of the second electrode or the second intermediate electrode. The first intermediate electrode and the second intermediate electrode may be arranged in contact with each other.

In various embodiments, the first intermediate electrode and the second intermediate electrode may be separate or distinct intermediate electrodes. The first intermediate electrode and the second intermediate electrode may include different materials to one another.

In the context of various embodiments, each of the first and second electrodes may be or may include an (electrochemically) inert electrode. The first intermediate electrode may be or may include a reactive electrode, and the second intermediate electrode may be or may include an oxygen scavenging electrode.

In the context of various embodiments, the first electrode may be or may include a reactive electrode, and the second electrode may be or may include an oxygen scavenging electrode. The intermediate electrode arrangement, or each of the first and second intermediate electrodes may be or may include an (electrochemically) inert electrode.

In the context of various embodiments, the oxygen scavenging electrode may include or be made of an oxygen scavenging material that may be oxidizable (e.g., the material may include an oxidizable element). This may mean that the oxygen scavenging material may be capable of forming an oxide, by combining with any available atomic oxygen or oxygen molecules.

In the context of various embodiments, the oxygen scavenging electrode may include at least one of a conductor, an alkaline earth metal, a transition metal, or a rare earth element, e.g., tantalum (Ta), titanium (Ti), hafnium (Hf), nickel (Ni), aluminum (Al), calcium (Ca), zirconium (Zr), magnesium (Mg), neodymium (Nd), ytterbium (Yb), lanthanum (La), yttrium (Y), erbium (Er), scandium (Sc), cerium (Ce), praseodymium (Pr), samarium (Sm), dysprosium (Dy), holmium (Ho), thulium (Tm), lutetium (Lu), etc., or an alloy thereof.

In the context of various embodiments, the reactive electrode may include at least one of copper (Cu) or silver (Ag).

In the context of various embodiments, the (electrochemically) inert electrode may include at least one of ruthenium (Ru), gold (Au), platinum (Pt), titanium nitride (TiN), tungsten (W), molybdenum (Mo), palladium (Pd), iridium (Ir), or other inert materials.

In various embodiments, the memory device 100 may be configured to provide a ratio of ON state/OFF state of at least 100 (i.e., 100), for example, 200, 500, or 1000. The ON state and the OFF state of the memory device 100 may be equivalent to the low and high resistance state respectively. In various embodiments, there might be more than 2 resistance states, thus the ON/OFF ratio may depend on which resistance states are being utilized.

FIG. 1B shows a method of forming a memory device, according to various embodiments. At 120, an electrochemical metallization memory (ECM) cell and a valence change memory (VCM) cell are arranged one over the other.

The ECM cell may include a first insulating layer, and the VCM cell may include a second insulating layer. The first insulating layer and the second insulating layer may be arranged offset from each other.

FIG. 1C shows a method for controlling a memory device, according to various embodiments. At 124, an electric field is applied to (or across) the memory device including an electrochemical metallization memory (ECM) cell and a valence change memory (VCM) cell arranged one over the other.

In various embodiments, at 124, application of the electric field may cause one or more conductive paths to be formed in one of the ECM cell and the VCM cell to define a first resistance state for the corresponding memory cell, and one or more conductive paths to be ruptured in the other of the ECM cell and the VCM cell to define a second resistance state for the corresponding memory cell. The formation and rupture of the associated one or more conductive paths may be at least substantially simultaneous.

In various embodiments, another electric field of an opposite polarity may be applied to (or across) the memory device. Application of the electric field of an opposite polarity may cause one or more conductive paths to be ruptured in the one of the ECM cell and the VCM cell to define the second resistance state for the corresponding memory cell, and one or more conductive paths to be formed in the other of the ECM cell and the

VCM cell to define the first resistance state for the corresponding memory cell. The formation and rupture of the associated one or more conductive paths may be at least substantially simultaneous.

FIG. 1D shows a schematic cross-sectional view of a memory array 110, according to various embodiments. The memory array 110 includes a plurality of first electrode lines 112a (or 114a, 114b), a plurality of second electrode lines 114a, 114b (or 112a), and a plurality of memory devices 100a, 100b, wherein, for each memory device of the plurality of memory devices 100a, 100b, the memory device 100a, 100b is arranged between a respective first electrode line of the plurality of first electrode lines 112a (or 114a, 114b) and a respective second electrode line of the plurality of second electrode lines 114a, 114b (or 112a), and is as described herein (for example, in the context of memory device 100). Descriptions are provided herein based on the non-limiting example of the plurality of first electrode lines (e.g., 112a) being provided on top of or over the plurality of second electrode lines (e.g., 114a, 114b), although it should be appreciated that the order of arrangement may be reversed. This may mean that, in various embodiments, the plurality of first electrode lines 112a may include or may define top electrode (TE) lines, while the plurality of second electrode lines 114a, 114b may include or may define bottom electrode (BE) lines, or vice versa.

A respective first electrode line of the plurality of first electrode lines 112a may electrically couple or may connect to at least one memory device of the plurality of memory devices 100a, 100b. A respective first electrode line of the plurality of first electrode lines 112a may be an extension of or may be separate from the first electrode of the at least one memory device of the plurality of memory devices 100a, 100b that is electrically coupled or connected to the respective first electrode line.

A respective second electrode line of the plurality of second electrode lines 114a, 114b may electrically couple or may connect to at least one memory device of the plurality of memory devices 100a, 100b. A respective second electrode line of the plurality of second electrode lines 114a, 114b may be an extension of or may be separate from the second electrode of the at least one memory device of the plurality of memory devices 100a, 100b that is electrically coupled or connected to the respective second electrode line.

It should be appreciated that while one first electrode line 112a and two second electrode lines 114a, 114b are illustrated, there may be any number of the plurality of first electrode lines and the plurality of second electrode lines, for example, two, three, four, five, six or any higher number.

It should be appreciated that while two memory devices 100a, 100b are illustrated, there may be any number of the memory devices, for example, two, three, four, five, six or any higher number. Further, it should be appreciated that while the two memory devices 100a, 100b are illustrated as being arranged in one row and two columns, the plurality of memory devices 100a, 100b may be arranged in any number of rows and/or columns, for example, in a grid-like arrangement. Further, it should be appreciated that while the two memory devices 100a, 100b are illustrated as being arranged in one layer, the plurality of memory devices 100a, 100b may be stacked on top of or over one another with a respective electrode between adjacent memory devices to form a multi-layer arrangement.

In various embodiments, the plurality of first electrode lines 112a may be arranged spaced apart from each other and/or the plurality of second electrode lines 114a, 114b may be arranged spaced apart from each other.

In various embodiments, the plurality of first electrode lines 112a may be arranged at least substantially parallel to one another, and/or the plurality of second electrode lines 114a, 114b may be arranged at least substantially parallel to one another.

In various embodiments, the plurality of first electrode lines 112a may extend longitudinally in or along a first direction, and the plurality of second electrode lines 114a, 114b may extend longitudinally in or along the first direction or a second direction different to the first direction.

In various embodiments, the plurality of second electrode lines 114a, 114b may be arranged crossing the plurality of first electrodes 112a. This may mean that the memory device (or a respective memory device) may be arranged at a cross-point of the respective first electrode line and the respective second electrode line.

In various embodiments, the plurality of first electrode lines 112a may extend in a first direction (e.g., as represented by arrow 117), and the plurality of second electrode lines 114a, 114b may extend in a second direction (e.g., as represented by arrow 116) at least substantially orthogonal to the first direction 117. This may mean that the memory array 110 may have a crossbar architecture.

In various embodiments, for each memory device 100a, 100b, the ECM cell and the VCM cell may be arranged coaxially, or co-aligned to each other. This may mean that the respective central axis of each of the ECM cell and the VCM cell may be co-aligned to each other.

In various embodiments, the memory array 110 may further include a plurality of intermediate (third) electrode lines, wherein the ECM cell of the memory device 100a, 100b may be arranged between the respective first electrode line 112a and a respective intermediate electrode line of the plurality of intermediate electrode lines, and the VCM cell of the memory device 100a, 100b may be arranged between the respective second electrode line 114a, 114b and the respective intermediate electrode line. A respective intermediate electrode line of the plurality of intermediate electrode lines may electrically couple or may connect to at least one memory device of the plurality of memory devices 100a, 100b. A respective intermediate electrode line of the plurality of intermediate electrode lines may be an extension of or may be separate from the first intermediate electrode and the second intermediate electrode, or the intermediate electrode, of the at least one memory device of the plurality of memory devices 100a, 100b that is electrically coupled or connected to the respective intermediate electrode line.

In various embodiments, the plurality of intermediate electrode lines may be arranged crossing the plurality of first electrode lines 112a and the plurality of second electrode lines 114a, 114b. This may mean that the ECM cell (or VCM cell) of the memory device 100a, 100b may be arranged at a cross-point of the respective first electrode line 112a and the respective intermediate electrode line, while the VCM cell (or ECM cell) of the memory device 100a, 100b may be arranged at a cross-point of the respective second electrode line 114a, 114b and the respective intermediate electrode line.

In various embodiments, the plurality of first electrode lines 112a and the plurality of second electrode lines 114a, 114b may extend in a first direction, and the plurality of intermediate electrode lines may extend in a second direction at least substantially orthogonal to the first direction. This may mean that the memory array 110 may have a crossbar architecture. The plurality of first electrode lines may be arranged at least substantially parallel to the plurality of second electrode lines.

In various embodiments, for each memory cell 100a, 100b, the ECM cell and the VCM cell may be arranged coaxially, or co-aligned to each other. This may mean that the respective central axis of each of the ECM cell and the VCM cell may be co-aligned to each other.

In various embodiments, for each memory device 100a, 100b, the ECM cell and the VCM cell may be arranged offset from each other. This may mean that the ECM cell and the VCM may not be arranged coaxially.

Throughout the description, an “ON-state” and an “OFF-state” are equivalent to low and high resistance states respectively. Further, an “SET process” may be defined as the switching of the (cell or device) resistance from the OFF-state to the ON-state, while the “RESET process” represents the opposite, which is switching from the ON-state to the OFF-state.

It should be appreciated that descriptions in the context of the memory device 100, the method of forming a memory device, the method for controlling a memory device, and the memory array 110 may correspondingly be applicable in relation to any one of the others as described herein.

Exemplary embodiments are related to a structure of anti-serially connected electrochemical metallization memory (ECM) and valence change memory (VCM) cells to achieve self-compliant characteristics and high ON/OFF resistance ratio. Step by step fabrication processes and details of the device operation are described herein.

The memory device of various embodiment, for example, having a RRAM structure, may include one ECM cell and one VCM cell connected anti-serially. The ECM cell may have a high ON/OFF resistance ratio. In one non-limiting example, a magnesium oxide (MgO) based ECM may be used. As a further non-limiting example, the main structure of an ECM cell may include, (Ta/Pt) or Ru/MgO/Cu/Ta/Pt on top of a SiO₂ wafer (e.g., a thermal oxide or silicon dioxide coated silicon wafer). This means that the ECM cell may include tantalum/platinum (Ta/Pt) or ruthenium (Ru), followed by magnesium oxide (MgO), copper (Cu), tantalum (Ta) and platinum (Pt). Ta may be used as a seeding layer to grow other materials. Generally, the main RRAM structure includes a metal/insulator/metal in the middle of the stack. Thus, Pt and Ru may be implemented as an inert electrode.

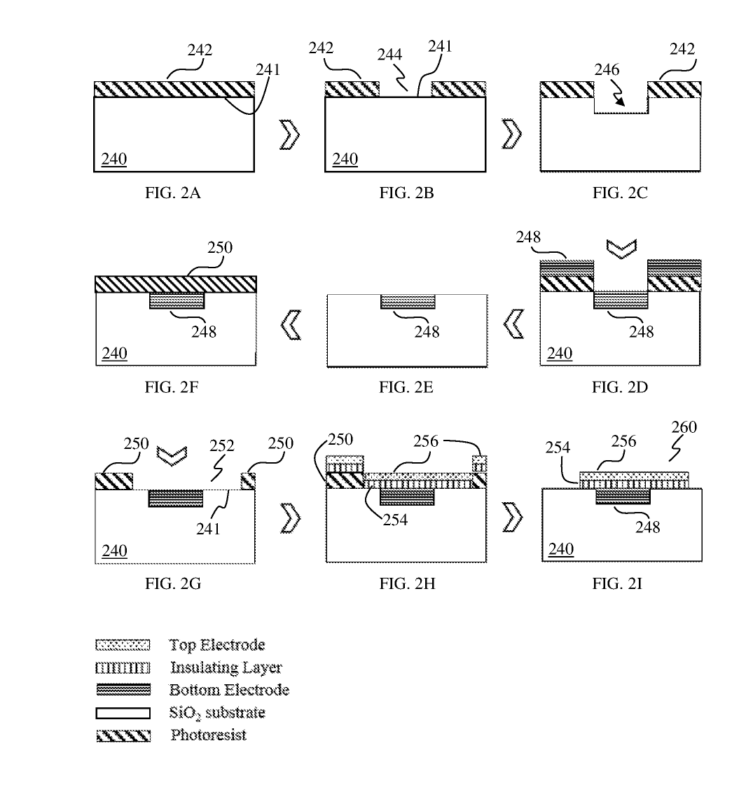

A single ECM crossbar device fabrication process is illustrated in FIGS. 2A to 2I. Referring to FIG. 2A, a substrate 240 may be provided, which may be a silicon substrate or wafer, or an oxide (SiO₂) coated silicon substrate. A photoresist 242 may be formed or deposited on or over the substrate 240, for example, on a top surface 241 of the substrate 240. Referring to FIG. 2B, a portion of the photoresist 242 may then be removed to define an opening or window 244. As illustrated in FIG. 2C, part of the substrate 240 exposed through the window 244 may be removed or etched away to define a recess 246 in the substrate 240.

Referring to FIG. 2D, material 248 for defining the bottom electrode may then be formed in the recess 246 and over the remaining photoresist 242, followed by removal of the remaining photoresist 242 and the material 248 located on the photoresist 242 (see FIG. 2E). As shown in FIG. 2E, a structure may be obtained having a bottom electrode 248 formed in the recess 246 of the substrate 240. The exposed surface of the bottom electrode 248 may be co-linear with the top surface 241 of the substrate 240. It should be appreciated that the positioning and/or size (or area) of the bottom electrode 248 may be defined by the window 244 created while the depth or height of the bottom electrode 248 may be defined by the depth of the recess 246 created.

Referring to FIG. 2F, another photoresist 250 may be formed or deposited on or over the bottom electrode 248 and the substrate 240. A portion of the photoresist 250 may be subsequently removed to define an opening or window 252 so as to expose bottom electrode 248 and the substrate 240 and part of the top surface 241 of the substrate 240 (see FIG. 2G).

Referring to FIG. 2H, a (blanket) deposition may be carried out such that an insulating layer 254 and material 256 for defining the top electrode may be formed in the recess 252 and over the remaining photoresist 250. The photoresist 250, and the insulating layer 254 and the material 256 on top of the photoresist 250, may then be removed. As shown in FIG. 2I, a structure 260 may be obtained, which may define an ECM cell. The structure 260 may have the bottom electrode 248, the insulating layer 254 over the bottom electrode 248, and the top electrode 256 over the insulating layer 254. It should be appreciated that the positioning and/or size (or area) of the insulating layer 254 and the top electrode 256 may be defined by the window 252 created while the total height of the insulating layer 254 and the top electrode 256 may be defined by the height of the photoresist 250 formed.

As a non-limiting example, the bottom electrode (BE) 248 may be patterned and formed using UV-lithography, followed by dry etching of the substrate (e.g., SiO₂ substrate) 240 and deposition of the BE material (e.g., Ta/Pt or Ru) 248 using DC magnetron sputtering. Patterning may then be carried out for forming the insulating layer (e.g., an oxide layer) 254 and the top electrode (TE) 256, followed by sputtering deposition of the materials using RF mode for the insulating layer (e.g., MgO) 254 and DC mode for the TE material (e.g., Cu/Ta/Pt) 256.

Referring to FIGS. 2A to 2I, in greater details, for example, the photoresist 242 may be a positive resist, where a part of the photoresist 242 may be exposed to UV (ultraviolet) radiation, which may then be developed and removed to form the window 244. The structure obtained (see FIG. 2B) may then be subjected to an etching process. For example, dry etching may be performed using an ion miling system to etch the portion of the substrate 240 exposed through the window 244 so as to create the recess 246 for forming the BE pattern. The material 248 may be deposited in the recess 246 and over the remaining photoresist 242 using DC magnetron sputtering. Where the BE material 248 is Ta/Pt, Ta acts as a seeding layer and Pt as the inert electrode material. The thickness of the bottom electrode 248 may be adjusted with the etching depth of the SiO₂ (substrate 240). The described method may be implemented to minimise or avoid a possible connection issue at the crosspoint (without this method, a thick top electrode (TE) may be subsequently required to ensure good connections) and to ensure a smooth surface for the second lithography step for defining the top electrode. Other than the etching process, similar steps may be repeated for the insulating layer (e.g., oxide layer) 254 and the top electrode layer 256.

Referring to FIGS. 2F and 2G, a positive photoresist 250 may be deposited, and a part of the photoresist 250 may then be exposed to UV (ultraviolet) radiation, which may subsequently be developed and removed to form the window 252. For the structure obtained (see FIG. 2G), the oxide layer (e.g., MgO) 254 may then be sputter deposited using the RF mode, and subsequently, the material 256 may be sputter deposited using the DC mode.

The process as described above may be replicated for fabricating a plurality of ECM cells, preferably in a concurrent manner Further, the process may similarly be applicable for fabricating one or more VCM cells.

The device effective area may be defined as the crosspoint between the TE and the BE, which may cover an area of approximately 900 nm². The as fabricated devices may then be annealed at 400° C. for 2 hours to ensure a good interface between the layers as well as to strengthen the polycrystalline MgO grain boundaries. The investigation of switching polarity of the device by varying the MgO layer thickness was performed to ensure only bipolar switching behaviour may be observed.

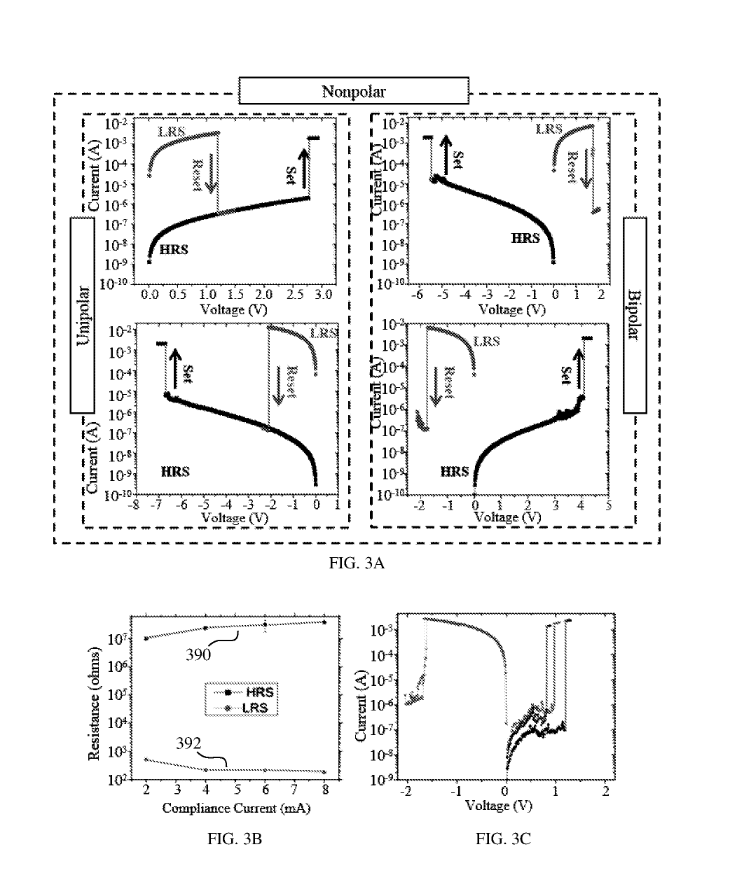

FIGS. 3A to 3C show plots of measurement data of MgO-based ECM structures. FIG. 3A shows IV (current-voltage) curves for a device structure having a thick oxide (MgO) layer (about 50 nm thick), in which nonpolar characteristics of the device may be observed. As illustrated in FIG. 3A, the device shows both unipolar and bipolar characteristics. For each pristine device, electroforming process by sweeping the voltage up to about 9 V may be required to initiate the switching process. During the SET operation, compliance current is necessary to be applied to avoid permanent damage to the device (no switching behaviour may be observed after the removal of compliance current). The SET and RESET voltages may be about 4-5 V and 1.5-1.7 V respectively for unipolar and bipolar modes.

FIG. 3B shows a plot illustrating the influence of preset compliance current towards the resistance ratio of the device. Results 390 for the high resistance state (HRS) and results 392 for the low resistance state (LRS) are shown. A resistance ratio of about 10⁴-10⁵ may be obtained by applying different compliance currents. This value is considered very high compared to known RRAM devices. This high ON/OFF ratio may be expected to give high endurance capability as reported for known Ta₂O₅₋ₓ/TaO₂₋ₓ based RRAM.

FIG. 3C shows IV (current-voltage) curves for a device structure having a thin oxide (MgO) layer (about 15 nm thick) (e.g., Pt/MgO/Cu device), in which the free-forming and self-compliant nature of the device may be observed. 3 different cycles of SET and RESET process of the device without compliance current are shown. It may be observed in FIG. 3C the self compliance characteristics of the device with a small variation in the SET current. Further, the unipolar mode may no longer be observed during operation. It may possibly be due to the inability of the device to dissipate the Joule heating generated by unipolar operation. The device may develop free-forming nature. Unlike the device with a thick MgO layer (e.g., see FIG. 3A), this device with the thin MgO layer may immediately start the switching operation. Further, the SET voltage observed may be smaller than the first structure (with the thick MgO layer), at about 0.7-1.4 V, and the RESET voltage may be relatively in the same range, while the resistance ratio of the device may be in the order of about 10⁴. An MgO based RRAM using a Pt/MgO/Pt structure is known to have a high resistance ratio; however the SET/RESET power is higher than the structure herein and the known structure requires preset compliance current during operation. Further, an MgO based RRAM with a Ru/MgO/TiOx/Ti structure is known to be self-compliant, but the ON/OFF ratio is much smaller than the structure herein.

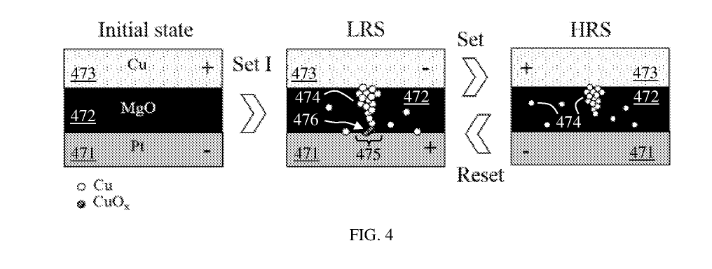

Further, there is no need to apply compliance current during the device operation because of the self-compliant nature of the device. Using a structure of Pt/MgO/Cu as a non-limiting example, while not wishing to be bound by any theory, this may likely be due to heat assisted oxidation of one or more copper filaments at several spots along the filament(s), including near the Pt electrode because Pt has the lowest heat conductivity among all layers. Referring to FIG. 4 for a structure of “platinum 471/magnesium oxide 472/copper 473” (Pt/MgO/Cu), at the low resistance state (LRS) when an electric field is applied to the structure with positive polarity to Pt 471 and negative polarity to Cu 473, copper ions 474 may migrate from the Cu layer 473 into the MgO layer 472 towards the Pt layer 471 and may form a conductive copper filament 475 throughout the (entire height of the) MgO layer 472. Oxidation of the Cu ions 474 may occur near the Pt layer 471 to form copper oxide (CuOₓ) 476. At the high resistance state (HRS) when an electric field is applied to the structure with positive polarity to Cu 473 and negative polarity to Pt 471, the copper filament 475 may be ruptured near to or towards the Pt layer 471, and, thus, the copper filament 475 may not extend through the entire MgO layer 472.

The free forming and self-compliant characteristics of a single ECM cell structure may exhibit variation in SET operating parameters (voltage and current). This might lead to increased device variability and retention degradation. On the other hand, the ON state resistance of the device may be relatively low, thus it may not be suitable for low current programming to achieve low power operation. In order to address or overcome these challenges, another memory cell, for example, VCM cell, may be implemented with the ECM cell, such that the resistance switching of each device may occur in complementary manner

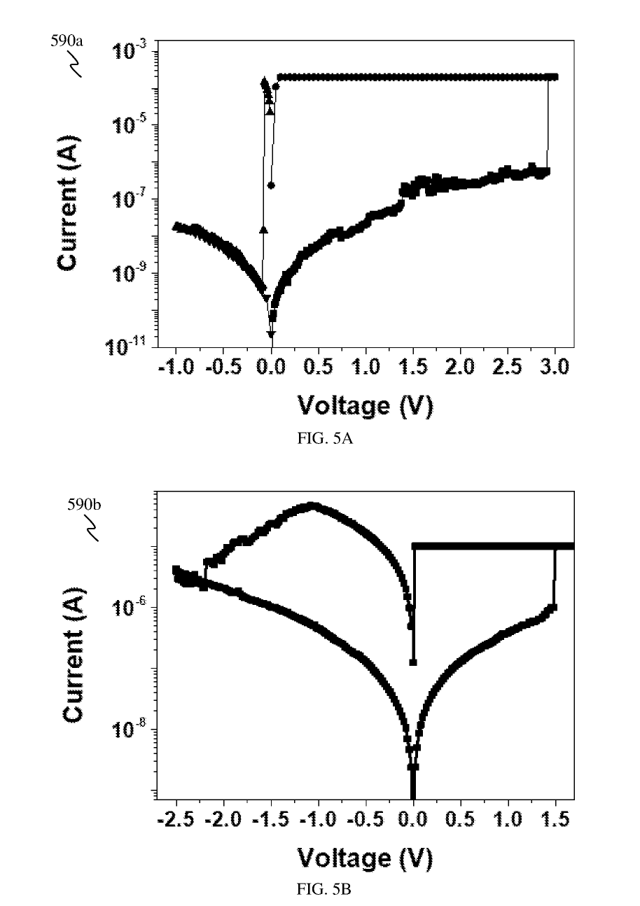

FIGS. 5A and 5B show plots of electrical measurement results of individual RRAM cells (an electrochemical metallization (ECM) cell and a valence change memory (VCM) cell). FIG. 5A shows a plot 590a of results for continuous DC measurement of a Ta/Ru/MgO/Cu/Ta/Ru ECM cell while FIG. 5B shows a plot 590b of results for continuous DC measurement of a Ta/Ru/MgO/Ta/Ru VCM cell.

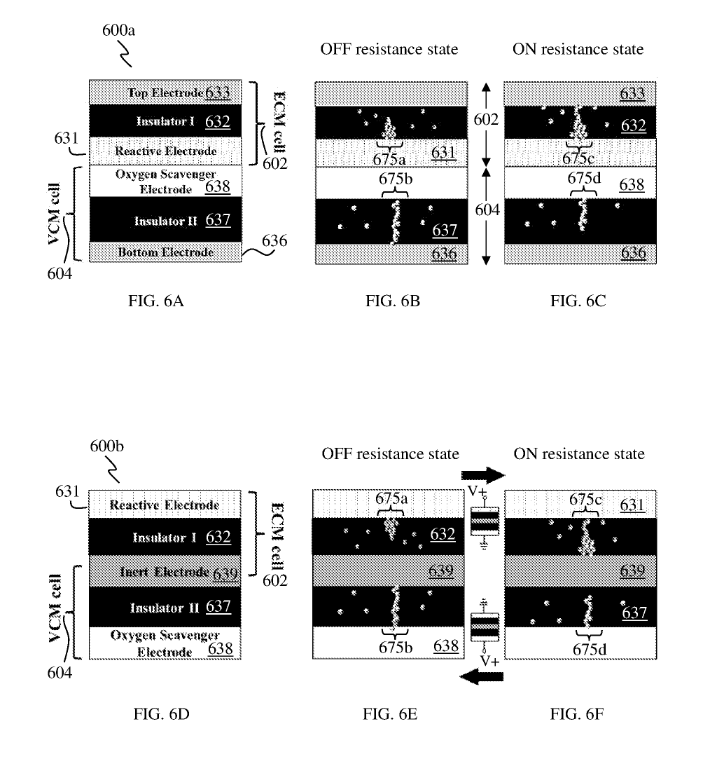

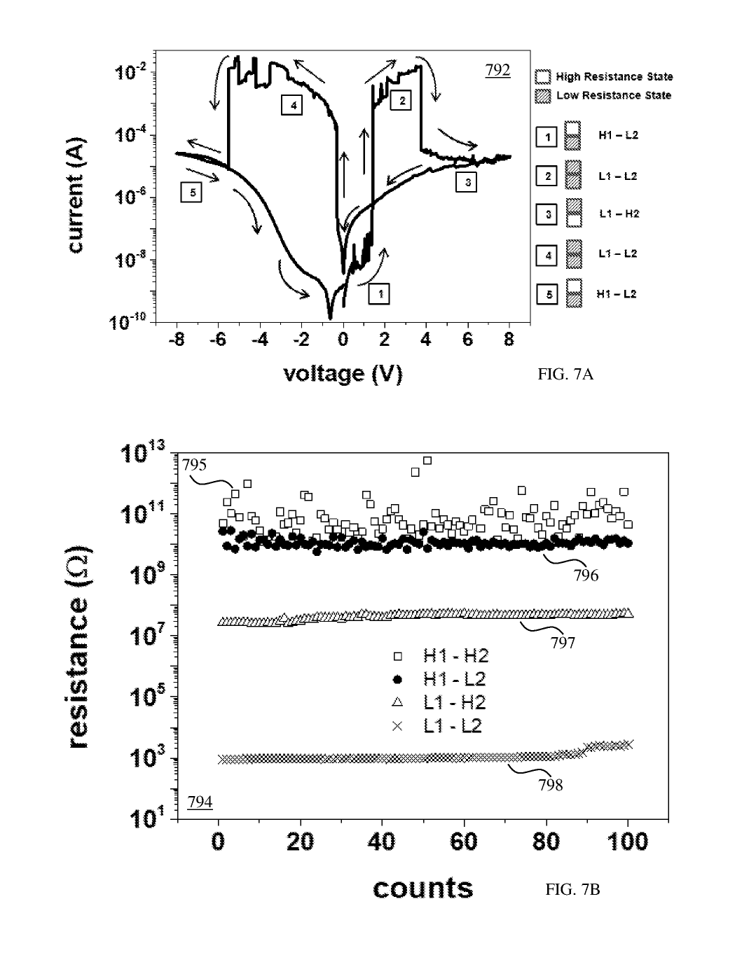

The presence of a VCM cell, together with an ECM cell, in a memory device, may lead to several changes. Firstly, the electroforming process may be required to initiate the switching in the (pristine) device, unless the (pristine) VCM cell has a low initial resistance state. The electroforming process of the entire memory device (e.g., RRAM stack) may be indicated by the formation of conductive filaments in the VCM cell region of the (pristine) device. This may be done to achieve a self-compliant forming process. Secondly, the VCM cell may act as a current limiter in the event of formation of conductive filaments in the ECM cell and vice versa, thus allowing self-compliant operation throughout the operation. Thirdly, SET process of the device may be indicated by the simultaneous formation and rupture of conductive filaments in the ECM cell and the VCM cell respectively to obtain an overall ON state, while on the contrary, the RESET process may be indicated by simultaneous rupture and formation of those respective filaments in the ECM cell and the VCM cell. As non-limiting examples, the device operation mechanisms may be as illustrated in FIGS. 6A to 6G and 7A.

FIG. 6A shows a cross-sectional view of a memory device (e.g., RRAM structure) 600a with an electrochemical metallization memory (ECM) cell 602 and a valence change memory (VCM) cell 604 connected in series. The ECM cell 602 may be arranged over or on top of the VCM cell 604, although this sequence may be reversed. The ECM cell 602 and the VCM cell 604 may be arranged in contact with each other.

The ECM cell 602 may include a reactive electrode 631, an insulator 632 over the reactive electrode 631, and another electrode (e.g., top electrode (TE)) 633 over the insulator 632. The electrode 633 may be an (electrochemically) inert electrode. The insulator 632 may be in contact with the reactive electrode 631 and the electrode 633. The reactive electrode 631, the insulator 632 and the electrode 633 may be provided in a stack arrangement or layered arrangement.

The VCM cell 604 may include an electrode (e.g., bottom electrode (BE)) 636, an insulator 637 over the bottom electrode 636, and an oxygen scavenger electrode 638 over the insulator 637. The electrode 636 may be an (electrochemically) inert electrode. The insulator 637 may be in contact with the oxygen scavenger electrode 638 and the electrode 636. The electrode 636, the insulator 637 and the oxygen scavenger electrode 638 may be provided in a stack arrangement or layered arrangement.

In various embodiments, the resistance switching of the ECM cell 602 and the VCM cell 604 may occur in a complementary manner. Conductive filaments may be formed in the two insulators 632, 637. In operation, when an electric field is applied to the memory device 600a, one or more conductive filaments may be formed throughout (the entire height of) one of the insulators 632, 637, and one or more conductive filaments may be ruptured in the other of the insulators 632, 637.

Referring to FIG. 6B illustrating an overall OFF resistance state configuration for the memory device 600a, the RESET process of the device 600a may be indicated by the rupture of the conductive filament 675a in the ECM cell 602 and the formation of the conductive filament 675b in the VCM cell 604 to obtain an overall OFF state. Referring to FIG. 6C illustrating an overall ON resistance state configuration for the memory device 600a, the SET process of the device 600a may be indicated by the formation of a conductive filament 675c in the ECM cell 602 and the rupture of a conductive filament 675d in the VCM cell 604 to obtain an overall ON state. The ruptured and formed filaments 675a, 675c in the ECM cell 602 may be associated with the same filament. The formed and ruptured filaments 675b, 675d in the VCM cell 604 may be associated with the same filament. In various embodiments, the device 600a, in the OFF resistance state (FIG. 6B), may be switched to the ON resistance state (FIG. 6C) by the application of a positive bias (e.g., V+) to the electrode 636 relative to the electrode 633 (e.g., which may be grounded or negatively biased by V−). Further, the device 600a, in the ON resistance state (FIG. 6C), may be switched to the OFF resistance state (FIG. 6B) by the application of a positive bias (e.g., V+) to the electrode 633 relative to the electrode 636 (e.g., which may be grounded or negatively biased by V−).

FIG. 6D shows a cross-sectional view of a memory device (e.g., RRAM structure) 600b with an electrochemical metallization memory (ECM) cell 602 and a valence change memory (VCM) cell 604. The ECM cell 602 may be arranged over or on top of the VCM cell 604, although this sequence may be reversed. The ECM cell 602 and the VCM cell 604 may be arranged in contact with each other. The memory device 600b is similar to the memory device 600a (FIG. 6A) except that the ECM cell 602 includes a reactive electrode 631 as the top electrode and an (electrochemically) inert electrode 639 sandwiching an insulator 632, while the VCM cell 604 includes an oxygen scavenger electrode 638 as the bottom electrode and the inert electrode 639 sandwiching an insulator 637.

In various embodiments, the resistance switching of the ECM cell 602 and the VCM cell 604 of memory device 600b may occur in a complementary manner at least substantially similar to that of the memory device 600a. Referring to FIG. 6E illustrating an overall OFF resistance state configuration for the memory device 600b, the RESET process of the device 600b may be indicated by the rupture of the conductive filament 675a in the ECM cell 602 and the formation of the conductive filament 675b in the VCM cell 604 to obtain an overall OFF state. Referring to FIG. 6F illustrating an overall ON resistance state configuration for the memory device 600b, the SET process of the device 600b may be indicated by the formation of a conductive filament 675c in the ECM cell 602 and the rupture of a conductive filament 675d in the VCM cell 604 to obtain an overall ON state. The ruptured and formed filaments 675a, 675c in the ECM cell 602 may be associated with the same filament. The formed and ruptured filaments 675b, 675d in the VCM cell 604 may be associated with the same filament. In various embodiments, the device 600b, in the OFF resistance state (FIG. 6E), may be switched to the ON resistance state (FIG. 6F) by the application of a positive bias (e.g., V+) to the reactive electrode 631 relative to the oxygen scavenger electrode 638 (e.g., which may be grounded or negatively biased by V−). Further, the device 600b, in the ON resistance state (FIG. 6F), may be switched to the OFF resistance state (FIG. 6E) by the application of a positive bias (e.g., V+) to the oxygen scavenger electrode 638 relative to the reactive electrode 631 (e.g., which may be grounded or negatively biased by V−).

In the device or structure of various embodiments, the dissolution of conductive filaments in one cell may limit the current flowing (formation of the filaments) in the other cell during the switching process, thus minimizing or preventing permanent damage on the device. Such a mechanism reflects the self-compliant characteristics of the memory device of various embodiments.

In various embodiments, the ECM and VCM cells (e.g., 602, 604) are connected anti-serially. As a result, one or more compatibility measures may be employed to obtain a high ON/OFF ratio and/or efficient switching process. The overall ON state resistance value may be determined by the high resistance state of the single VCM cell (e.g., 604), while the overall OFF state may follow the high resistance state of the ECM cell (e.g., 602). Thus, in order to achieve a high ON/OFF ratio, the high resistance state of the ECM cell may be preferred to be significantly higher than that of the VCM cell. The overall ON resistance value may be higher compared to a single ECM or VCM cell, thus, reducing power consumption. The memory device or structure of various embodiments may increase the ON-state resistance value while providing sufficiently large ON/OFF resistance window, thus resulting in low power consumption and low bit-error rate. During the switching cycles, voltage shift may occur between the ECM cell and the VCM cell. Simultaneous conductive filaments formation and rupture in different regions (or cells) of the device may occur or may only occur if the SET voltages of the ECM and VCM cells are smaller than the voltage across each region (or cell) if conductive filaments are to exist in both ECM and VCM cells.

There may be challenges in connecting an ECM cell and a VCM cell to one another, for example when connected anti-serially together. One challenge may be to design or ensure the cells' compatibility in terms of SET/RESET voltage and current as well as ON and OFF resistance states to minimize ΔV, this referring to the voltage window in which both the ECM and VCM cells are in low resistance state. The operating principles of the devices of various embodiments are different from known devices employing complementary resistive switching working principles. As another challenge, the degradation of the one or more intermediate electrode(s) may also be an issue. Where these challenges are addressed or overcome, an ECM cell and a VCM cell may be connected together to work as a memory device.

It should be appreciated that, minimizing or removing ΔV may be required if the corresponding resistance state in the range of ΔV is not of interest. The memory device includes or consists of an ECM cell and a VCM cell connected in anti-serial manner or in series ignoring the switching polarity of the cells. During the switching operation, the external voltage applied to the device (V_{TOTAL}) may be divided into two, e.g., the voltage across the ECM cell (V_{ECM}) and the voltage across the VCM cell (V_{VCM}), while the current flowing through both cells are equal. In order to remove ΔV, this may require the simultaneous switching process from both the ECM and VCM cells. For example, referring to FIG. 6E, in order to switch the device 600b from OFF to ON resistance states with zero ΔV, V_{TOTAL}=V_{ECM}+V_{VCM} in which at the start of the switching process, V_{ECM} is sufficient to initiate the SET process for the ECM cell 602, while V_{VCM} is also sufficiently high to initiate the RESET process on the VCM cell 604.

In minimizing the degradation of the intermediate electrode to avoid intermixing between the ECM cell 602 and the VCM cell 604, the memory device 600b may be preferable over the memory device 600a. Relatively higher risk of intermixing on the device 600a may be due to the fact that the reactive electrode 631 has a higher mobility that may cause undesired diffusion, for example, at an elevated temperature. Thus, for the device 600a, an additional diffusion barrier between the reactive electrode 631 and the oxygen scavenging electrode 638 may be provided. Non-limiting examples for the diffusion barrier, for copper as the reactive electrode 631, may include titanium nitride (TiN), tantalum nitride (TaN), and titanium zirconium nitride (TiZrN), which is considered as refractory metal nitride, while, for silver material as the reactive electrode 631, non-limiting examples for the diffusion barrier may include tungsten (W), titanium nitride (TiN), tantalum (Ta), tantalum nitride (TaN), tantalum-oxide-nitride (Ta—O—N), tantalum-silicon-nitride (Ta—Si—N), and titanium-tungsten (Ti—W).

FIG. 7A shows a plot 792 of full IV (current-voltage) loop for a memory device of various embodiments, illustrating the IV characteristics for different high and low resistance states for the two memory cells of the memory device. The voltage sweep was done from 0 to 8 V, 8 V to −8 V, and −8 V to 0, and the measurement results are as shown in FIG. 7A, illustrating the different resistance states of the individual memory cells (e.g., RRAM) and the respective result at corresponding parts of the IV loop. As may be observed, two different resistance states may be provided at the regions corresponding to “1” and “3”. Further, as illustrated, ΔV of the memory device is different for positive and negative bias conditions. The ΔV window may be observed in the voltage range of 1.7V to 3.8V (ΔV=2.1V) and −0.5V to −5.5V (ΔV=5V).

FIG. 7B shows a plot 794 of resistance for different high and low resistance states for the two memory cells of a memory device of various embodiments. The resistance measurements may be performed by applying a constant voltage stress to the memory device and measuring the current flowing across it. The parameter “counts” for the x-axis represents the n^{th} reading during the measurement. The distance between two of the data points is about 0.1 s. Plot 794 shows results (represented as open squares 795) for the two memory cells having high resistance states, results (represented as closed circles 796) for the upper memory cell having a high resistance state and the lower memory cell having a low resistance state, results (represented as open triangles 797) for the upper memory cell having a low resistance state and the lower memory cell having a high resistance state, results (represented as crosses 798) for the two memory cells having low resistance states. In various embodiments, there may be more than 2 resistance states, thus the ON/OFF ratio may depend on which resistance states are being utilized. The resistance values for results 795, 796, 797, and 798 in FIG. 7B may be unique to the intrinsic resistivity of the implemented insulating layers, e.g., for both the ECM and VCM cells, and the resistivity of the conductive bridge that may form during the switching operation, e.g., the reactive electrode of the ECM cell and the oxygen scavenging electrode for the VCM cell.

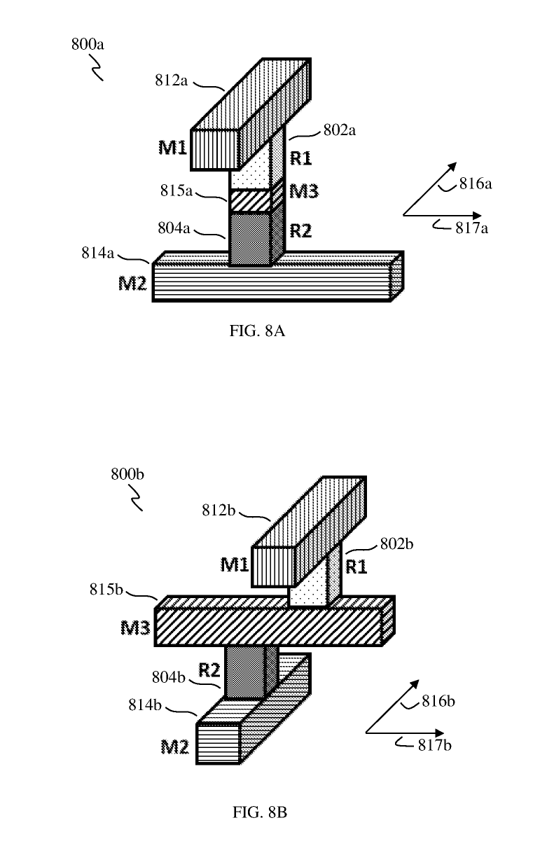

The memory devices and memory arrays of various embodiments may be implemented in a number of arrangements or architectures. As non-limiting examples, FIGS. 8A and 8B show two different arrangements that may be implemented.

Referring to FIGS. 8A and 8B, each of the memory devices 800a, 800b may include a first electrode (M1) 812a, 812b, a first insulating layer (R1) 802a, 802b, an intermediate (or third) electrode (M3) 815a, 815b, a second insulating layer (R2) 804a, 804b, and a second electrode (M2) 814a, 814b. The first electrode 812a, 812b, and the second electrode 814a, 814b may be in the form of an electrode line extending longitudinally. The intermediate electrode 815a, 815b may be arranged in contact with the first insulating layer 802a, 802b, and the second insulating layer 804a, 804b.

The first electrode 812a, 812b, the first insulating layer 802a, 802b, and the intermediate electrode 815a, 815b, may define a first memory cell (e.g., ECM cell) of the memory device 800a, 800b, and the intermediate electrode 815a, 815b, the second insulating layer 804a, 804b, and the second electrode 814a, 814b may define a second memory cell (e.g., VCM cell) of the memory device 800a, 800b. The intermediate electrode 815a, 815b may be a common intermediate electrode shared by the first and second memory cells or may include a 2-layer arrangements having a first intermediate electrode proximal to the first insulating layer 802a, 802b and forming part of the first memory cell, and a second intermediate electrode proximal to the second insulating layer 804a, 804b and forming part of the second memory cell.

Referring to FIG. 8A, the first electrode 812a and the second electrode 814a may be arranged crossing each other. This may mean that the memory device 800a may have a crossbar architecture. The first insulating layer 802a and the second insulating layer 804a may be arranged at a cross-point of the first electrode 812a and the second electrode 814a. The first electrode 812a may extend in or along a first direction 816a and the second electrode 814a may extend in or along a second direction 817a orthogonal to the first direction 816a. The first insulating layer 802a and the second insulating layer 804a may be arranged coaxially, or co-aligned to each other. The intermediate electrode 815a may be arranged coaxially, or co-aligned to the first insulating layer 802a and the second insulating layer 804a.

Referring to FIG. 8B, the intermediate electrode 815b may be in the form of an electrode line extending longitudinally. The intermediate electrode 815b may be arranged crossing the first electrode 812b and the second electrode 814b. This may mean that the memory device 800b may have a crossbar architecture. The first insulating layer 802b may be arranged at a cross-point of the first electrode 812b and the intermediate electrode 815b, and the second insulating layer 804b may be arranged at a cross-point of the second electrode 814b and the intermediate electrode 815b. The first electrode 812b and the second electrode 814b may be arranged at least substantially parallel to each other. The first electrode 812b and the second electrode 814b may extend in or along a first direction 816b and the intermediate electrode 815b may extend in or along a second direction 817b orthogonal to the first direction 816b. The first insulating layer 802b and the second insulating layer 804b may be arranged offset from each other, meaning that the first and second insulating layers 802b, 804b may not be arranged coaxially

It should be appreciated that the architectures as described with reference to FIGS. 8A and 8B may be extended to memory arrays. Using the arrangement of FIG. 8A as a non-limiting example, a plurality of memory devices 800a may be provided arranged along the first direction 816a and the second direction 817a. A plurality of first electrodes extending in the first direction 816a may be provided, spaced apart from each other in the second direction 817a. A plurality of second electrodes extending in the second direction 817a may be provided, spaced apart from each other in the first direction 816a. Using the first electrode 812a as an example, the first electrode 812a may electrically couple one or more memory devices spaced apart from each other, with each of the one or more memory devices electrically coupled to a respective second electrode of the plurality of second electrodes. Using the second electrode 814a as an example, the second electrode 814a may electrically couple one or more memory devices spaced apart from each other, with each of the one or more memory devices electrically coupled to a respective first electrode of the plurality of first electrodes. Memory arrays using the architecture illustrated in FIG. 8B may be correspondingly provided as described above in the context of the arrangement of FIG. 8A.

For the arrangement illustrated in FIG. 8A, a small device area and/or a simple fabrication process may be provided. 2-3 resistance states may be provided. There may be a challenge in that the intermediate electrode 815a may be prone to permanent damage, thereby causing intermixing between the first insulating layer 802a and the second insulating layer 804a.

For the arrangement illustrated in FIG. 8B, four or more resistance states (i.e., >4 resistance states) may be provided. There may be minimal or no risk of intermixing between the first insulating layer 802b and the second insulating layer 804b. However, there may be one or more challenges in that a large device area and/or more lithography steps may be required.

In various embodiments, as non-limiting examples, the materials that may be used may include any one of the following:
first electrode (e.g., oxygen scavenging electrode) 812a, 812b=Ta;
second electrode (e.g., reactive electrode) 814a, 814b=Cu;
intermediate electrode (electrochemically inert electrode) 815a, 815b=Ru, Au, Pt;

first insulating layer 802a, 802b=MgO, HfOx;
second insulating layer 804a, 804b=MgO, HfOx.

However, it should be appreciated that other materials may be used for any of the electrodes and/or insulating layers as provided below:
first electrode 812a, 812b=Ti, Hf, Ni, Al, Ca, Zr, etc, or rare earth elements (e.g., Nd, Yb, La, Y, etc);
second electrode 814a, 814b=Ag;
intermediate electrode 815a, 815b=TiN, W, Mo, Pd, Ir, etc;
first insulating layer 802a, 802b=other oxide materials (e.g., TaOx, AlOx, SiOx, ZnO, etc);
second insulating layer 804a, 804b=other oxide materials (e.g., TaOx, AlOx, SiOx, ZnO, etc), or chalcogenide-based materials (e.g., GeS₂, GeSex, GeTe, Cu₂S, Ag₂S, etc), or amorphous materials (e.g., Si₃N₄, Si, etc).

In various embodiments, extremely reactive oxygen scavenging material, such as, e.g., Er, La, Y, Yb, Sc, Ce, Pr, Nd, Sm, Dy, Ho, Tm, Yb, Lu or other rare earth elements may be employed, although other conductors such as, e.g., Hf, Ni, Al, Ti, Ca, Mg, Zr, etc. or their alloys may also be employed.

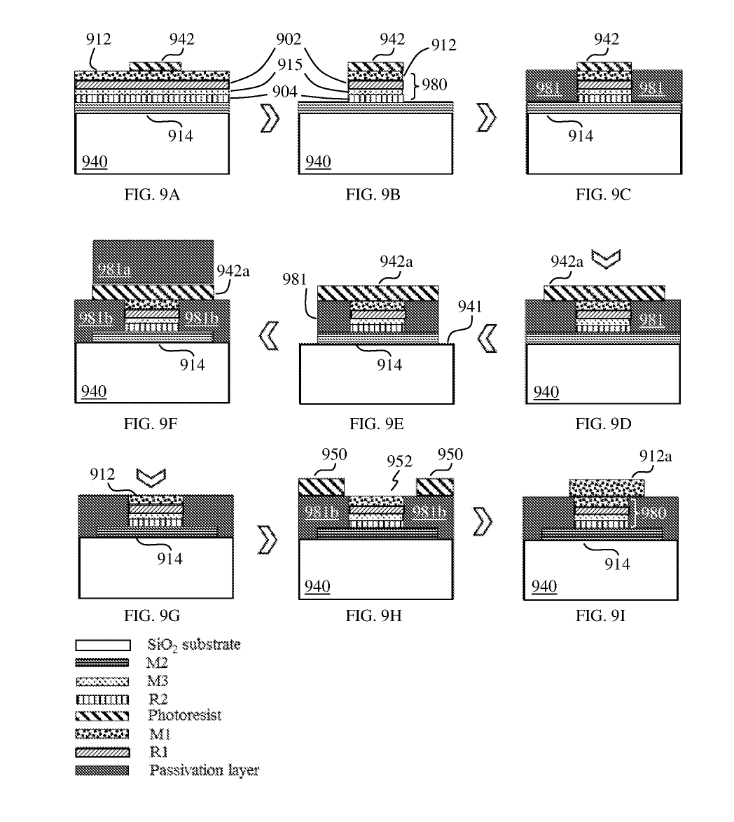

FIGS. 9A to 9I show, as cross-sectional views, various processing stages of a method for fabricating a memory device, according to various embodiments. This method may be suitable for forming the memory device 800a having an arrangement as illustrated in FIG. 8A. The fabrication process may begin with the deposition of the entire material stack, followed by pillar patterning. Referring to FIG. 9A, a substrate 940 may be provided, which may be a silicon substrate or wafer, or an oxide (SiO₂) coated silicon substrate. A second electrode (M2) 914, a second insulating layer (R2) 904, an intermediate electrode (M3) 915, a first insulating layer (R1) 902, and a first electrode (M1) 912, may be deposited, in sequence, on the substrate 940. A photoresist 942 may be formed or deposited on or over the first electrode 912, and then patterned to maintain a portion of the photoresist 942 on the first electrode 912. Referring to FIG. 9B, the remaining photoresist 942 may act as a mask for etching of the second insulating layer 904, the intermediate electrode 915, the first insulating layer 902, and the first electrode 912 to define a pillar 980. Referring to FIG. 9C, a passivation layer 981 may be deposited on the sides of or around the pillar 980. The photoresist 942 may be removed.

The process may then continue with bottom electrode patterning. Referring to FIG. 9D, a photoresist 942a may be deposited on or over the first electrode 912 and the passivation layer 981, and then patterned to maintain a portion of the photoresist 942a. Referring to FIG. 9E, the remaining photoresist 942a may act as a mask for etching of the passivation layer 981 and the second electrode (as the bottom electrode) 914.

Another passivation step may be carried out, for example to overlap or cover the exposed top surface 941 of the substrate 940. Referring to FIG. 9F, a passivation layer 981a may be deposited on the remaining photoresist 942a, and a passivation layer (together with the passivation layer 981) 981b may be formed on the sides of or around the pillar 980 and the remaining second electrode 914. Referring to FIG. 9G, the remaining photoresist 942a and the passivation layer 981a may then be removed.

The process may then continue with top electrode patterning. Referring to FIG. 9H, another photoresist 950 may be deposited on or over the first electrode 912 and the passivation layer 981b. A portion of the photoresist 950 may be subsequently removed to define an opening or window 952 so as to expose first electrode 912 and part of the passivation layer 981b. Referring to FIG. 9I, material for the first electrode 912 may then be formed in the window 952 to define another electrode or an extension 912a of the first electrode 912. The remaining photoresist 950 may then be removed.

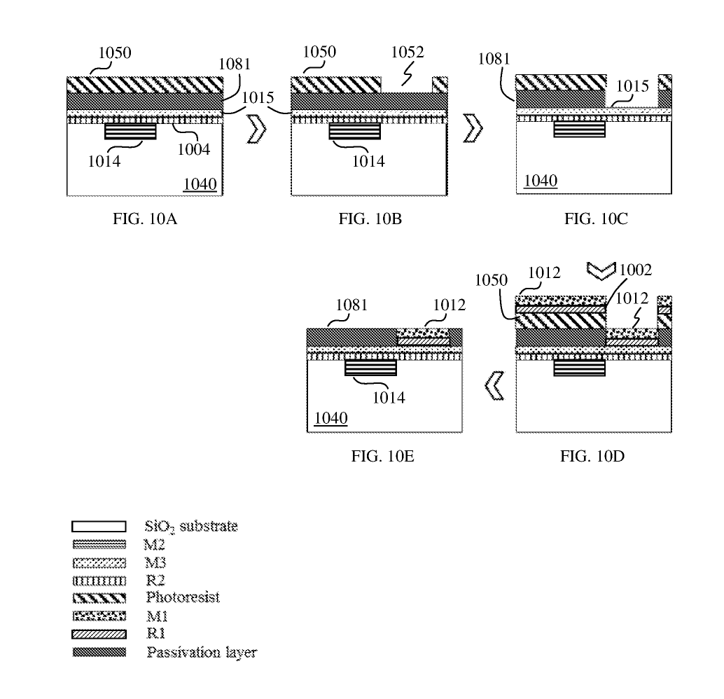

FIGS. 10A to 10E show, as cross-sectional views, various processing stages of a method for fabricating a memory device, according to various embodiments. This method may continue from the method as described in the context of FIGS. 2A to 2I, and may be suitable for forming the memory device 800b having an arrangement as illustrated in FIG. 8B.

Starting from the structure as shown in FIG. 2E, the process may then continue to the process as illustrated in FIGS. 10A to 10E, with the substrate labelled as 1040 and the second electrode labeled as 1014. Referring to FIG. 10A, a second insulating layer (R2) 1004, an intermediate electrode (M3) 1015, a passivation layer 1081, and a photoresist 1050, may then be deposited, in sequence, on the substrate 1040 and the second electrode (M2) 1014. Referring to FIG. 10B, a portion of the photoresist 1050 may be subsequently removed to define an opening or window 1052 so as to expose part of the passivation layer 1081. The window 1052 may be created offset from the second electrode 1014. As illustrated in FIG. 10C, part of the passivation layer 1081 exposed through the window 1052 may be removed or etched away to expose part of the intermediate electrode 1015.

Referring to FIG. 10D, materials for a first insulating layer (R1) 1002, and a first electrode (M1) 1012, may then be deposited, in sequence, on the exposed intermediate electrode 1015 and on the remaining photoresist 1050. Referring to FIG. 10E, the remaining photoresist 1050 and the layers thereon may then be removed. The top surface of the first electrode 1012 may be co-linear with the top surface of the passivation layer 1081.

The memory devices of various embodiments and their associated structures may exhibit self-compliant characteristics. In this way, in the structure, the dissolution of conductive filaments in one cell may limit the current flowing (formation of the filaments) in the other cell during the switching process, thus helping to minimise or prevent oxide breakdown in the structure. As such, while the device structure or stack may include (two) thin oxide layers (e.g., as the insulating layers), for example, in the range of few tens of nm, the integrity of the oxide layers and, hence, the reliability of the devices is not likely to be compromised as a result of the self-compliant characteristics.

In ECM and VCM cells, ions migration is triggered by an external electric field (E) provided by an external bias. The structure of various embodiments may increase the ON-state resistance value of the corresponding memory device (e.g., RRAM device). Assuming the electric field required to reset the device is Eᵣₑₛₑₜ, the voltage, Vᵣₑₛₑₜ, required is directly proportional to Eᵣₑₛₑₜ. A small amount of current, Iᵣₑₛₑₜ, may be enough to provide the Vᵣₑₛₑₜ because the value of the ON state resistance, Rₒₙ, is higher, thus resulting in low power consumption, Pᵣₑₛₑₜ, (where, in general P_{reset>}Pₛₑₜ). Vᵣₑₛₑₜ and Pᵣₑₛₑₜ may be determined using the following equations.

Vᵣₑₛₑₜ=Iᵣₑₛₑₜ×Rₒₙ (Equation 1),

Pᵣₑₛₑₜ=Iᵣₑₛₑₜ²×Rₒₙ (Equation 2).

The ON state resistance, Rₒₙ, is expected to be between 10⁴-10⁵Ω while the RESET current, Iᵣₑₛₑₜ, is estimated to be about 10 μA, thus, the power consumption, Pᵣₑₛₑₜ, is expected to be about 10 μW or lower. Furthermore, the low power consumption is also related to the self-compliant characteristics of the device. It may prevent over-SET during the operation. Over-SET might result in formation of (too) strong conductive filaments that may lead to high power requirement to reset the device.

As described above, various embodiments may provide a memory device and the associated entire fabrication process that may achieve free forming self-compliant characteristics, and high ON/OFF ratio with RRAM structure including (anti-serially connected) ECM and VCM cells.

The memory cells of various embodiments may be written/erased and read with standard RRAM cell operation, in which a higher ON-state resistance (low power consumption) may be achieved while maintaining a large ON/OFF ratio.

Various embodiments of the memory device may be MgO based, for example, employing MgO-based memory cells; however, it should be appreciated that other oxides or chalcogenides may be employed. The memory device of various embodiments may have an ON/OFF ratio of more than 100 (i.e., >100). The memory device may have an operating power of about 1 μW, while for known devices, the operating power may be tens of μW or even hundreds of μW. The memory device or memory array of various embodiments may employ a 1R (1 resistor) memory architecture, as compared to 1T1R (1 transistor−1 resistor) or 1S1R (1 selector−1 resistor) architecture for known devices.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A memory device comprising an electrochemical metallization memory (ECM) cell and a valence change memory (VCM) cell arranged one over the other.

2. The memory device as claimed in claim 1, wherein, in response to an electric field applied to the memory device, one or more conductive paths are formed in one of the ECM cell and the VCM cell to define a first resistance state for the corresponding memory cell, and one or more conductive paths are ruptured in the other of the ECM cell and the VCM cell to define a second resistance state for the corresponding memory cell.

3. The memory device as claimed in claim 2, wherein, in response to another electric field of an opposite polarity applied to the memory device, one or more conductive paths are ruptured in the one of the ECM cell and the VCM cell to define the second resistance state for the corresponding memory cell, and one or more conductive paths are formed in the other of the ECM cell and the VCM cell to define the first resistance state for the corresponding memory cell.

4. The memory device as claimed in claim 1,
wherein the ECM cell comprises a first insulating layer, and
wherein the VCM cell comprises a second insulating layer.

5. The memory device as claimed in claim 4, wherein the first insulating layer and the second insulating layer are arranged offset from each other.

6. (canceled)

7. (canceled)

8. The memory device as claimed in claim 4,
wherein the ECM cell comprises a first electrode and an intermediate electrode arrangement sandwiching the first insulating layer, and
wherein the VCM cell comprises a second electrode and the intermediate electrode arrangement sandwiching the second insulating layer.

9. The memory device as claimed in claim 8, wherein the intermediate electrode arrangement comprises a first intermediate electrode and a second intermediate electrode.

10. The memory device as claimed in claim 1, wherein the memory device is configured to provide a ratio of ON state/OFF state of at least 100.

11. A method of forming a memory device comprising arranging an electrochemical metallization memory (ECM) cell and a valence change memory (VCM) cell one over the other.

12. The method as claimed in claim 11,
wherein the ECM cell comprises a first insulating layer, and
wherein the VCM cell comprises a second insulating layer.

13. The method as claimed in claim 12, wherein the first insulating layer and the second insulating layer are arranged offset from each other.

14. A method for controlling a memory device comprising applying an electric field to the memory device comprising an electrochemical metallization memory (ECM) cell and a valence change memory (VCM) cell arranged one over the other.

15. The method as claimed in claim 14, further comprising applying another electric field of an opposite polarity to the memory device.

16. A memory array comprising:
a plurality of first electrode lines;
a plurality of second electrode lines; and
a plurality of memory devices,
wherein, for each memory device of the plurality of memory devices, the memory device comprises an electrochemical metallization memory (ECM) cell and a valence change memory (VCM) cell arranged one over the other, and the memory device is arranged between a respective first electrode line of the plurality of first electrode lines and a respective second electrode line of the plurality of second electrode lines.

17. The memory array as claimed in claim 16, wherein the plurality of second electrode lines are arranged crossing the plurality of first electrodes.

18. The memory array as claimed in claim 17,
wherein the plurality of first electrode lines extend in a first direction, and
wherein the plurality of second electrode lines extend in a second direction at least substantially orthogonal to the first direction.

19. The memory array as claimed in claim 16, further comprising a plurality of intermediate electrode lines,
wherein the ECM cell of the memory device is arranged between the respective first electrode line and a respective intermediate electrode line of the plurality of intermediate electrode lines, and
wherein the VCM cell of the memory device is arranged between the respective second electrode line and the respective intermediate electrode line.

20. The memory array as claimed in claim 19, wherein the plurality of intermediate electrode lines are arranged crossing the plurality of first electrode lines and the plurality of second electrode lines.

21. The memory array as claimed in claim 19,
wherein the plurality of first electrode lines and the plurality of second electrode lines extend in a first direction, and
wherein the plurality of intermediate electrode lines extend in a second direction at least substantially orthogonal to the first direction.

22. The memory array as claimed in claim 19, wherein, for each memory device, the ECM cell and the VCM cell are arranged offset from each other.
